(19) United States
(12) Patent Application Publication
(10) Pub. No.: US 2012/0273876 A1
(43) Pub. Date: Nov. 1, 2012

(54) SEMICONDUCTOR DEVICE AND METHOD FOR FORMING THE SAME

(75) Inventor: Han Nae KIM, Seoul (KR)

(73) Assignee: Hynix Semiconductor Inc., Icheon-si (KR)

(21) Appl. No.: 13/347,477

(22) Filed: Jan. 10, 2012

(30) Foreign Application Priority Data
Apr. 27, 2011 (KR) 10-2011-0039691

(51) Int. Cl. H01L 29/78; H01L 21/336

(52) U.S. Cl. 257/330; 438/270; 257/E29.262; 257/E21.41

(57) ABSTRACT

A semiconductor device and a method for forming the same are disclosed. The semiconductor device includes a semiconductor substrate that includes a cell region and a peripheral circuit area. The method for forming the semiconductor includes forming a guard pattern of an insulation material. The guard pattern is located at an edge part between the cell region and the peripheral circuit region and is buried in the semiconductor substrate. As a result, the semiconductor device prevents oxidation of the guard pattern, such that a cell gate oxidation integrity (GOI) failure is improved and an IDD failure is prevented from being generated.

### CROSS-REFERENCE TO RELATED APPLICATION

The priority of Korean patent application No. 10-2011-0039691 filed on 27 Apr. 2011, the disclosure of which is hereby incorporated in its entirety by reference, is claimed.

### BACKGROUND OF THE INVENTION

The present invention relates to a semiconductor device, and more particularly to a semiconductor device and a method for forming the same.

Recently, most of electronic appliances include a semiconductor device. The semiconductor device includes electronic elements such as a transistor, a resistor and a capacitor. These electronic elements are integrated on a semiconductor substrate. For example, an electronic appliance such as a computer or a digital camera includes a memory chip for storing information and a processing chip for controlling the information. The memory chip and the processing chip include electronic elements integrated on a semiconductor substrate.

The semiconductor devices have a need for an increase in an integration degree thereof in order to satisfy consumer demands for superior performances and low prices. Such an increase in the integration degree of the semiconductor device entails a reduction in a design rule, which may substantially reduce patterns of the semiconductor device. Although an entire chip area is increased in proportion to an increase in a memory capacity as the semiconductor device is becoming super miniaturized and highly integrated, a cell area where patterns of the semiconductor device are actually formed is decreased. Accordingly, since a greater number of patterns should be formed in a limited cell area in order to achieve a desired memory capacity, there is a need for formation of microscopic (fine) patterns having a reduced critical dimension.

However, an exposure device for implementing a fine pattern required for the increasing integration degree of the semiconductor device does not keep up with rapid development of associated technology.

A representative method for forming such a fine pattern is a Double Patterning Technology (DPT). The DPT may be classified into a Double Expose Etch Technology (DE2T) and a Spacer Patterning Technology (SPT) that uses a spacer. The DE2T uses at least one pattern having a time period corresponding to two times (2×) a desired pattern period.

The spacer pattering technology (SPT) may be classified into a positive spacer patterning technology and a negative patterning technology. 30 nm-class semiconductor devices have been generally patterned using the positive spacer patterning technology. For example, a 40 nm-class device isolation film has been formed using single patterning, and a 30 nm-class 6F2 device isolation film has been formed using the spacer patterning technology. However, as the semiconductor device is gradually reduced in size due to higher integration thereof, critical dimension (CD) uniformity of a pattern formed by the positive space patterning may be reduced, resulting in the generation of a leaning pattern.

Meanwhile, as a structure including a buried gate is proposed to achieve higher integration of the semiconductor device, an electrode of the buried gate is oxidized by an oxidant gas applied to a cell region when forming a gate oxide film in a peripheral circuit region. This may result in the occurrence of a cell Gate Oxidation Integrity (GOI) failure.

Thus, a guard pattern may be formed at a border between the cell region and the peripheral circuit region. However, if such a guard pattern is damaged or destroyed in a region shared by an N-well and a P-well because of a plurality of subsequent etching processes, a leakage path between a high voltage Vpp and a back-bias voltage Vbb is generated, resulting in the occurrence of an Isolation Driven Development (IDD) failure.

FIG. 1 illustrates a cross-sectional view of a conventional semiconductor device. FIG. 2 illustrates a Transmission Electron Microscope (TEM) representation of a cross-sectional view of a conventional semiconductor device including a damaged guard pattern.

Referring to FIG. 1, active regions 14A and 14B defined by device isolation layers 12A, 12B, and 12C are formed over a semiconductor substrate 11 that includes a cell region 10 and a peripheral circuit region 50. In addition, a guard pattern 13 is formed at a border between the cell region 10 and the peripheral circuit region 50.

Subsequently, after forming a mask pattern 16 that defines trenches over the active region 14A and the device isolation layer 12A in the cell region 10, the active region 14A and the device isolation layer 12A are etched using the mask pattern 16 as a mask. This results in trench formation.

Subsequently, an electrode material is formed in a lower portion of each of the trenches, and then a gate 18 is formed in the trenches. After that, an insulation layer 20 is formed over the gate 18, and an interlayer insulation layer 22 is formed over the insulation layer 20.

Thereafter, the interlayer insulation layer 22 is partially etched to expose a portion of the active region 14A, which is disposed between two adjacent gates. A conductive layer is buried in a region where the interlayer insulation layer 22 is removed and the active region 14A is exposed, so that a bit line contact plug 24 is formed.

However, when subsequently performing an oxidation process to form a gate oxide film in the peripheral circuit region 50, an oxidation path 26 via which a top part of the guard pattern 13 can be oxidized may be generated. Through the oxidation path 26, the top part of the guard pattern 13 may be oxidized.

In addition, as shown in A of FIG. 2, the guard pattern 13 may be damaged during a mask/etch process to open the cell region 10 or the peripheral circuit region 50, so that a crack may be generated in the guard pattern 13. This crack A in the guard pattern 13 may generate a current path between an N-well and a P-well and thus cause an IDD failure in a region shared by the N-well and the P-well.

### BRIEF SUMMARY OF THE INVENTION

Various embodiments of the present invention are directed to providing a semiconductor device and a method for forming the same, which may substantially obviate one or more problems due to limitations and disadvantages of the related art.

Embodiments of the present invention relate to a semiconductor device and a method for forming the same, which can solve the problems of the conventional semiconductor device in which a guard pattern is oxidized in an oxidation process for forming a gate oxide film in a peripheral circuit region and/or damaged in a mask/etch process performed to open a cell region or the peripheral circuit region.

In accordance with an aspect of the present invention, a semiconductor device includes a semiconductor substrate including a cell region and a peripheral circuit region; and a guard pattern disposed in the semiconductor substrate at a border between the cell region and the peripheral circuit region, wherein the guard pattern includes an insulation material.

The guard pattern may include a nitride layer.

The semiconductor device may further include an active region defined by a device isolation layer and disposed in the cell region.

The semiconductor device may further include a gate disposed in the active region or in the device isolation layer of the cell region.

In accordance with another aspect of the present invention, a method for forming a semiconductor device includes providing a semiconductor substrate including a cell region and a peripheral circuit region and forming a guard pattern in the semiconductor substrate, wherein the guard pattern is located at a border between the cell region and the peripheral circuit region and includes an insulation material.

The method may further include, before the forming of the guard pattern, forming a device isolation layer in the semiconductor substrate to define an active region.

The forming of the guard pattern may include, if the device isolation layer is formed at the border between the cell region and the peripheral circuit region, forming a trench by etching a portion of the device isolation layer formed at the border, forming an insulation layer within the trench and performing a planarization etching process on the insulation layer so as to expose the device isolation layer.

The insulation film may include a nitride film.

The forming of the guard pattern may include, if the active region is located at the border between the cell region and the peripheral circuit region, forming a trench by etching a portion of the active region at the border, forming an insulation layer to fill the trench and performing a planarization etching process on the insulation layer so as to expose the active region.

The method may further include, after the forming of the guard pattern, forming a gate in the active region or in the device isolation layer of the cell region.

### BRIEF DESCRIPTION OF THE DRAWINGS

FIG. 1 illustrates a cross-sectional view of a conventional semiconductor device.

FIG. 2 is a Transmission Electron Microscope (TEM) representation illustrating a cross-sectional view of a conventional semiconductor device including a damaged guard pattern.

FIGS. 3a and 3b are plan views illustrating a method for forming a semiconductor device according to an embodiment of the present invention.

FIG. 4 illustrates a cross-sectional view of a semiconductor device according to an embodiment of the present invention.

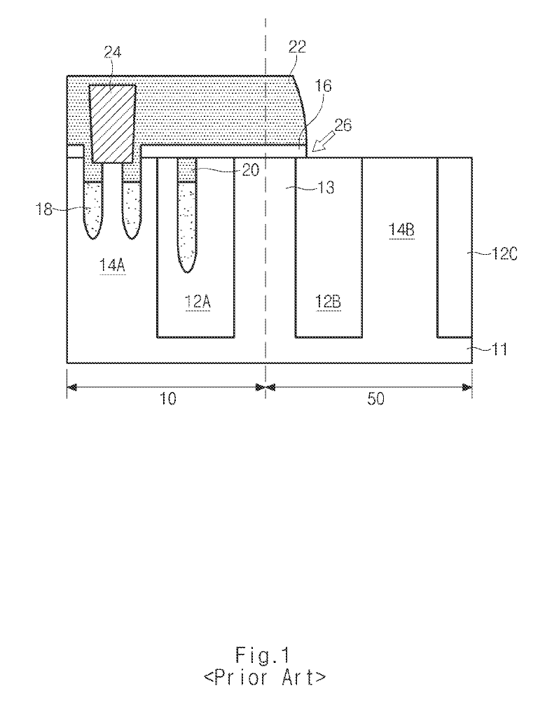

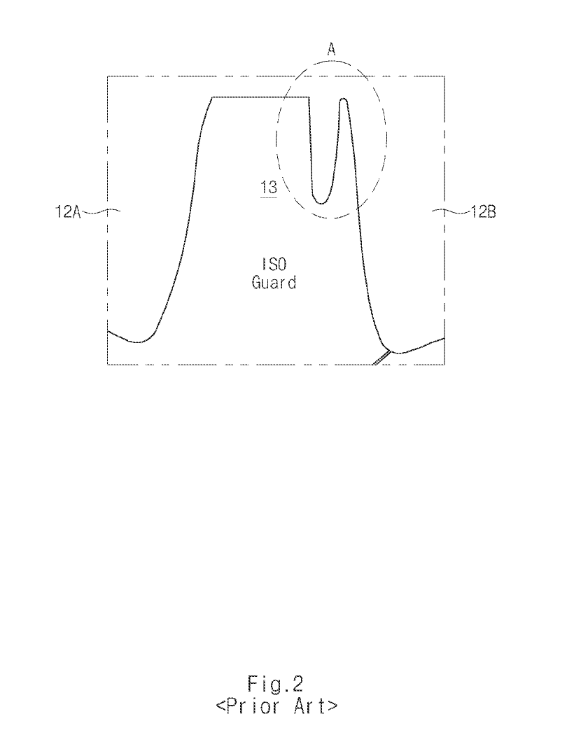

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts.

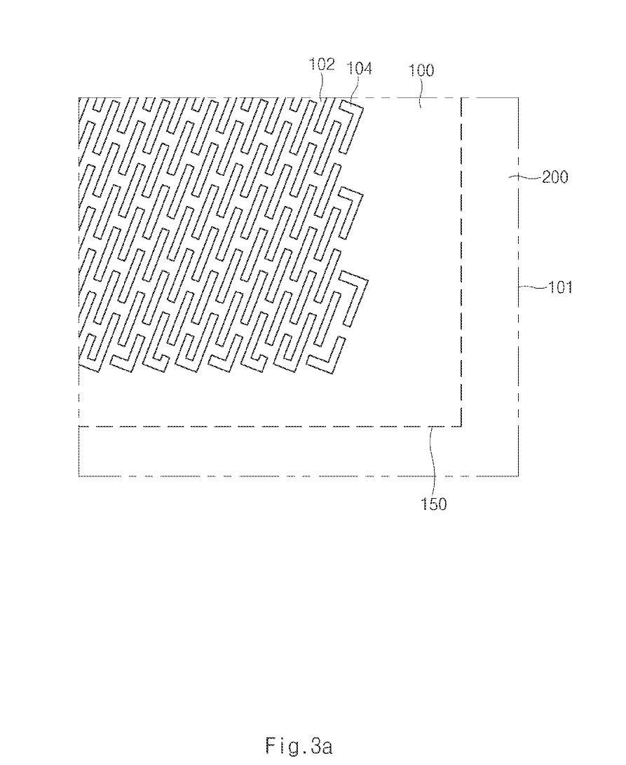

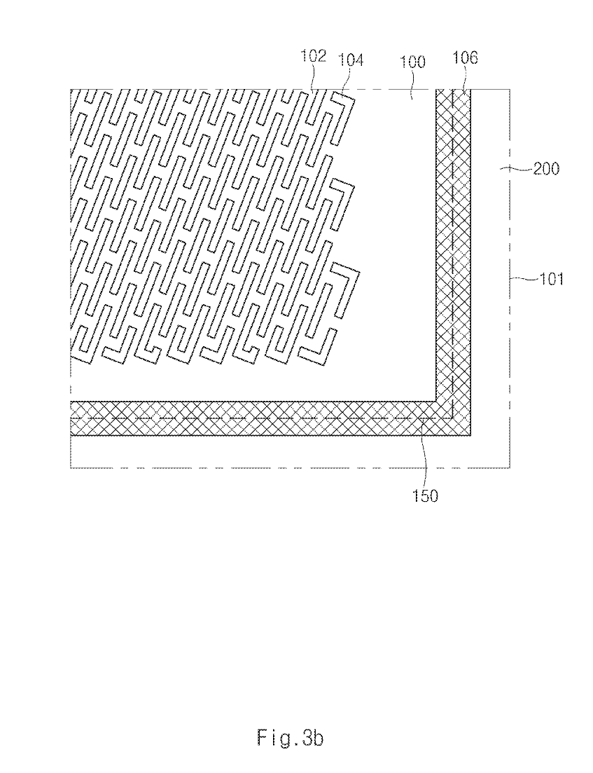

FIGS. 3a and 3b are plan views illustrating a method for forming a semiconductor device according to an embodiment of the present invention.

Referring to FIG. 3a, an active region 104 defined by a device isolation layer 102 is formed in a cell region 100 over a semiconductor substrate 101 that includes the cell region 100 and a peripheral circuit region 200. A device isolation layer 102 or an active region 104 may be formed at a border 150 between the cell region 100 and the peripheral circuit region 200. The device isolation layer 102 and the active region 104 may be formed by processes described below.

After forming a partition pattern (not shown) over a portion of the semiconductor substrate 101 that corresponds to the cell region 100, a spacer (not shown) is formed on both sidewalls of the partition pattern. The partition pattern (not shown) may include a diagonal line-and-space pattern.

Subsequently, the partition pattern is removed and a spacer pattern (not shown) is then formed using a cutting mask pattern. The semiconductor substrate 101 is etched using the spacer pattern as a mask such that a device isolation region is formed. Thereafter, an insulation material fills the device isolation region to form the device isolation layer 102. In accordance with an embodiment, the insulation layer may include spin on dielectric (SOD). The active region 104 is defined by the device isolation layer 102.

Referring to FIG. 3b, a guard pattern 106 is formed at the border 150 between the cell region 100 and the peripheral circuit region 200. In accordance with an embodiment, the guard pattern 106 may be configured in a line type and be formed to cover the border 150. Although it is not shown, the guard pattern 106 may be formed through processes described below.

In accordance with an embodiment, when the guard pattern 106 is formed in the device isolation layer 102 that is formed at the border 150 between the cell region 100 and the peripheral circuit 200, a portion of the device isolation layer 102 formed at the border 150 is removed to form a trench therein.

In accordance with another embodiment, when the guard pattern 106 is formed in the active region 104 that is disposed at the border 150, the trench may be formed by etching a portion of the active region 104 disposed at the border 150.

Subsequently, an insulation layer is formed to cover the trench. After that, a planarization etching process may be performed on the insulation layer to expose the device isolation layer 102 or the active region 104 at the border 150, resulting in formation of the guard pattern 106.

The insulation layer buried in the trench may include a material that is not oxidized in an oxidation process of forming the gate oxide film. In accordance with an embodiment, the insulation layer includes a nitride layer. The planarization etching process may include a chemical mechanical polishing (CMP) process.

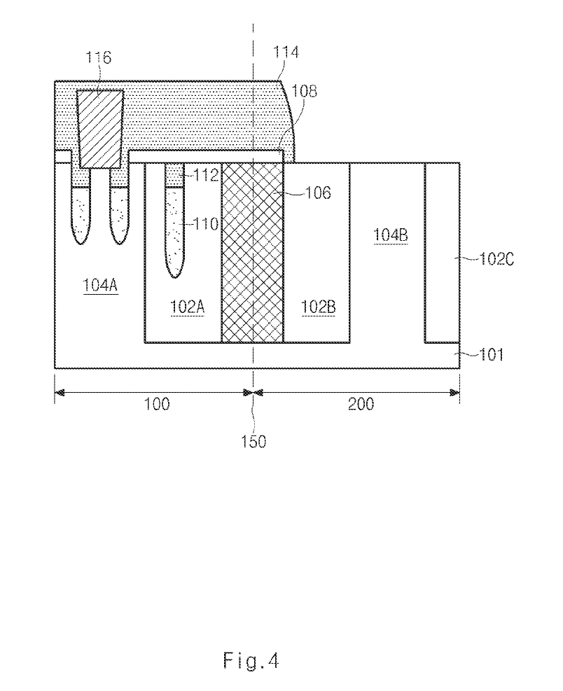

FIG. 4 illustrates a cross-sectional view of a semiconductor device according to an embodiment of the present invention.

The active regions 104A and 104B defined by device isolation layers 102A, 120B, and 102C are formed over a semiconductor substrate 101 that includes a cell region 100 and a peripheral circuit region 200.

The active region 104A in the cell region 100 may be formed in a diagonal line-and-space pattern. In addition, a border 150 between the cell region 100 and the peripheral circuit region 200 may include the device isolation layer or the active region.

The device isolation layers 102A and 102B are formed by etching a portion of a device isolation layer formed at the border 150.

Subsequently, a region where the portion of the device isolation layer is removed at the border 150. It is then filled with an insulation layer including a material that is not oxidized in a subsequent oxidation process, thereby forming a guard pattern 106 between the device isolation layers 102A and 102B.

After that, a mask pattern 108 defining trenches is formed over the device isolation layer 102A and the active region 104A in the cell region 100. The active region 104A and the device isolation layer 102A in the cell region 100 are then partially etched using the mask pattern 108 as a mask so as to form the trenches.

An electrode material is then buried in a lower portion of each of the trenches to form a gate 110. The gate 110 may include a barrier metal layer and a metal layer. In an embodiment, the barrier metal layer may include a titanium nitride (TiN) material, and the metal layer may include tungsten (W).

Subsequently, an insulation layer 112 and an interlayer insulation layer 114 are sequentially formed over the gate 110. The interlayer insulation layer 114 is partially etched to expose a portion of the active region 104A, which is disposed between two adjacent gates, and a conductive layer is buried in a region where the interlayer insulation layer 114 is removed and the active region 104A is exposed, so that a bit line contact plug 116 is formed.

In this embodiment, since the guard pattern 106 is formed of an insulation film that is not oxidized in the oxidation process, the guard pattern 106 is not damaged in the oxidation process of forming a gate oxide film in the peripheral circuit region 200. In addition, since this embodiment of the guard pattern 106 includes a nitride layer, the guard pattern 106 may not be attacked by a subsequent mask/etch process of exposing the cell region 100 or the peripheral circuit region 200. As a result, the guard pattern 106 can substantially prevent a leakage path between Vpp and Vbb from being generated, so that an IDD failure may be prevented.

As described above, an embodiment of a semiconductor device according to the present invention may be configured to include the guard pattern formed of an insulation layer that is not oxidized in an oxidation process at the border between the cell region and the peripheral circuit region, such that the guard pattern can be substantially prevented from being damaged in a subsequent oxidation process and/or a subsequent mask/etch process. As a result, a GOI failure and an IDD failure may be prevented.

The above embodiment of the present invention is illustrative and not limitative. Various alternatives and equivalents are possible. The invention is not limited by the embodiment described herein. Nor is the invention limited to any specific type of semiconductor device. Other additions, subtractions, or modifications are obvious in view of the present disclosure and are intended to fall within the scope of the appended claims.

What is claimed is:

1. A semiconductor device comprising:
a semiconductor substrate including a cell region and a peripheral circuit region; and
a guard pattern disposed in the semiconductor substrate at a border between the cell region and the peripheral circuit region, wherein the guard pattern includes an insulation material.

2. The semiconductor device according to claim 1, wherein the guard pattern includes a nitride layer.

3. The semiconductor device according to claim 1, further comprising:
an active region defined by a device isolation layer and disposed in the cell region.

4. The semiconductor device according to claim 3, further comprising:
a gate disposed in the active region or in the device isolation layer of the cell region.

5. The semiconductor device according to claim 4 wherein the gate comprises a metal layer.

6. The semiconductor device according to claim 5 wherein the metal layer comprises tungsten.

7. The semiconductor device according to claim 4 wherein the gate comprises a barrier metal layer.

8. The semiconductor device according to claim 7 wherein the barrier metal layer comprises titanium nitride.

9. The semiconductor device according to claim 4 wherein the gate comprises a buried gate.

10. A method for forming a semiconductor, the method comprising:
providing a semiconductor substrate including a cell region and a peripheral circuit region; and
forming a guard pattern in the semiconductor substrate, wherein the guard pattern is located at a border between the cell region and the peripheral circuit region and includes an insulation material.

11. The method according to claim 10, further comprising:
before the forming of the guard pattern,
forming a device isolation layer in the semiconductor substrate to define an active region.

12. The method according to claim 11, wherein the forming of the guard pattern comprises:
if the device isolation layer is formed at the border between the cell region and the peripheral circuit region,
forming a trench by etching a portion of the device isolation layer formed at the border;
forming an insulation layer within the trench; and
performing a planarization etching process on the insulation layer so as to expose the device isolation layer.

13. The method according to claim 12, wherein the insulation layer includes a nitride layer.

14. The method according to claim 12, wherein the planarization etching process is performed through chemical mechanical polishing.

15. The method according to claim 11, wherein the forming of the guard pattern comprises:
if the active region is located at the border between the cell region and the peripheral circuit region,
forming a trench by etching a portion of the active region at the border;
forming an insulation layer to fill the trench; and
performing a planarization etching process on the insulation layer so as to expose the active region.

16. The method according to claim 15, wherein the insulation layer includes a nitride layer.

17. The method according to claim 15, wherein the planarization etching process is performed through chemical mechanical polishing.

18. The method according to claim 11, further comprising:
after the forming of the guard pattern,
forming a gate in the active region or in the device isolation layer of the cell region.

19. The method according to claim 18, wherein the forming of the gate comprises forming a buried gate.
